(19) United States
(12) Patent Application Publication
(10) Pub. No.: US 2026/0066010 A1
(43) Pub. Date: Mar. 5, 2026

(54) ENERGY RECYCLING IN MEMORY SYSTEMS

(71) Applicant: Micron Technology, Inc., Boise, ID (US)

(72) Inventors: Jonathan S. PARRY, Boise, ID (US); Liang YU, Boise, ID (US); Srivatsan VENKATESAN, Sandy, UT (US); Michele PICCARDI, Cupertino, CA (US); Jung Hee YUN, Fremont, CA (US)

(21) Appl. No.: 19/252,517

(22) Filed: Jun. 27, 2025

Related U.S. Application Data
(60) Provisional application No. 63/687,660, filed on Aug. 27, 2024.

(51) Int. Cl. G11C 16/30; G11C 5/06; G11C 16/32

(52) U.S. Cl. CPC G11C 16/30; G11C 5/063; G11C 16/32

(57) ABSTRACT

In some implementations, a memory system may perform a staggered access operation on a first access line of a first one or more access lines and a second access line of a one or more second access lines, the second access line coupled to the first access line, wherein the staggered access operation comprises a first activation of the first access line during a first duration and a second activation of the second access line during a second duration subsequent to the first duration.

### CROSS-REFERENCE TO RELATED APPLICATION

This Patent application claims priority to U.S. Provisional Patent Application No. 63/687,660, filed on Aug. 27, 2024, entitled “ENERGY RECYCLING IN MEMORY SYSTEMS,” and assigned to the assignee hereof. The disclosure of the prior Application is considered part of and is incorporated by reference into this Patent Application.

### TECHNICAL FIELD

The present disclosure generally relates to memory devices, memory device operations, and, for example, to energy recycling in memory systems.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system capable of energy recycling in memory systems.

FIG. 2 is a diagram illustrating an example memory architecture that may be used by the memory device.

FIG. 3 is a diagram of example components included in a memory device.

FIG. 4 shows an example of a system that supports energy recycling in memory systems.

FIG. 5 shows an example of a timing diagram that supports energy recycling in memory systems.

FIG. 6 shows an example of a system that supports energy recycling in memory systems.

FIG. 7 is a flowchart of an example method associated with energy recycling in memory systems.

FIG. 8 is a flowchart of an example method associated with energy recycling in memory systems.

### DETAILED DESCRIPTION

Some memory systems, including non-volatile memory systems such as NAND devices and volatile memory systems such as dynamic random access memory (DRAM) devices, may perform access operations using an array of word lines. Such access operations may include repeatedly charging and discharging the access lines. For example, a multi-pass programming operation may include a first phase in which a first programming voltage is applied to one or more access lines, a second phase in which the one or more access lines are discharged, and a third phase in which a second programming voltage is applied to the one or more access lines. Due to the capacitance of the access lines (e.g., the intrinsic capacitance), such charging and discharging may result in the generation and dissipation of heat, which may contribute to overall energy inefficiency.

Some implementations described herein enable energy recycling in memory systems. For example, a memory device of a memory system may include one or more blocks of memory cells. Such blocks may be included in the same plane, or may be included in separate planes. A block may include one or more access lines that may be used as part of access operations for memory cells of the block. The access lines of a first block may be coupled with the access lines of a second block, such as via one or more conductive paths. The memory device may perform a staggered programming operation to store data across a first access line of the first block and a second access line of the second block. For example, the staggered programming operation may include a first duration in which the first access line is activated and the second access line is deactivated. The staggered programming operation may include a second duration, subsequent to the first duration, in which the first access line is deactivated and the second access line is activated, as described in greater detail elsewhere herein. Due to the coupling of the first access line and the second access line, energy from the first access line may flow to the second access line during the second duration, which may aid in activating the second access line.

Additionally, a memory system may recycle energy between one or more memory devices via a voltage supply node using a reservoir capacitor. For example, a memory device may include a recycle circuit configured to selectively couple one or more access lines of the memory device to the reservoir capacitor of the memory system. The recycle circuit may include a switching component configured to determine whether voltage of the access line(s) satisfies a threshold, such as whether the voltage of the access line(s) is greater than the voltage of the voltage supply node. If the switching component determines that the voltage of the access line(s) does not satisfy the threshold, then the switching component may isolate the access line(s) from the reservoir capacitor. Alternatively, if the switching component determines that the voltage of the access line(s) satisfies the threshold, then the switching component may couple the access line(s) to the reservoir capacitor. Such coupling may cause energy to flow from the access line(s) to the reservoir capacitor, and the memory system may use the provided energy to assist in other operations of the one or more memory devices.

As a result, by enabling energy recycling in memory systems, a memory device and/or the memory system may reduce the amount of energy used to perform access operations. For example, by staggering programming operations, a memory device may transfer energy that would otherwise be lost (e.g., dissipated as heat) from the first access line to the second access line. Such energy transfer may reduce the amount of energy generated by the memory device to activate the second access line, thus reducing power consumption of the memory device. Further, such energy transfer may reduce dissipated heat, which may improve the efficiency and/or effectivity of thermal management. Additionally, by selectively coupling access line(s) of a memory device to the reservoir capacitor, the memory device may provide energy to the reservoir capacitor that would otherwise be lost, such as via heat dissipation or other mechanisms. The reservoir capacitor to may redistribute the provided energy back to the memory device, and/or other memory devices of the memory system. Such redistribution may reduce the power consumption of the memory system. Further, recycling energy may reduce the amount of energy used to access a given amount of data (e.g., may reduce the energy per bit). Such reduced energy per bit may allow the memory device to perform additional operations in the case of an unexpected power loss, which may improve the reliability of the memory system as described in greater detail elsewhere herein.

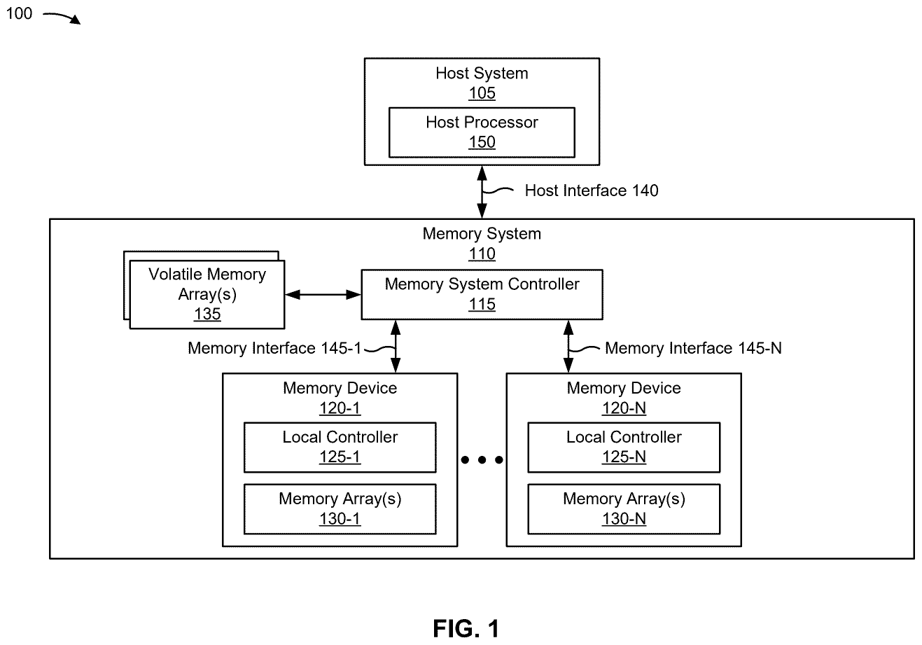

FIG. 1 is a diagram illustrating an example system 100 capable of energy recycling in memory systems. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a DRAM device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may include: a first one or more access lines; a second one or more access lines; and one or more controllers configured to: perform a staggered access operation on a first access line of the first one or more access lines and a second access line of the one or more second access lines, the second access line coupled to the first access line, wherein the staggered access operation comprises a first activation of the first access line during a first duration and a second activation of the second access line during a second duration subsequent to the first duration.

In some implementations, one or more systems, devices, apparatuses, components, and/or controllers of FIG. 1 may be configured to activate, as part of a staggered access operation associated with a first one or more access lines and a second one or more access lines, a first access line of the first one or more access lines during a first duration; and activate, as part of the staggered access operation, a second access line of the second one or more access lines during a second duration subsequent to the first duration, wherein the second access line is coupled to the first access line.

In some implementations, one or more systems, devices, apparatuses, components, and/or controllers of FIG. 1 may include: one or more access lines; a voltage pad configured to couple to a reservoir capacitor; and a recycle circuit configured to selectively couple the one or more access lines to the reservoir capacitor via the voltage pad or isolate the one or more access lines from the reservoir capacitor based on a first voltage of the one or more access lines.

In some implementations, one or more systems, devices, apparatuses, components, and/or controllers of FIG. 1 may include: a reservoir capacitor; a voltage supply node coupled to the reservoir capacitor; and a first memory device coupled to the voltage supply node, the first memory device comprising: a first one or more access lines; a voltage pad configured to couple to the reservoir capacitor; and a recycle circuit configured to selectively couple the first one or more access lines to the reservoir capacitor via the voltage pad or isolate the first one or more access lines from the reservoir capacitor based on a first voltage of the first one or more access lines.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

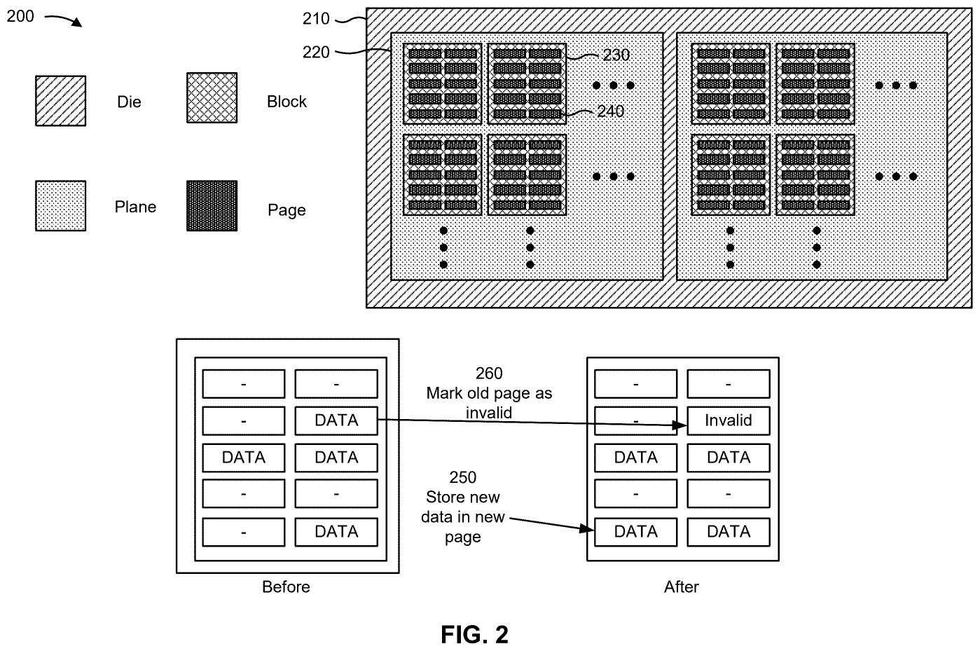

FIG. 2 is a diagram illustrating an example memory architecture 200 that may be used by the memory device 120. The memory device 120 may use the memory architecture 200 to store data. As shown, the memory architecture 200 may include a die 210, which may include multiple planes 220. A plane 220 may include multiple blocks 230. A block 230 may include multiple pages 240. Although FIG. 2 shows a particular quantity of planes 220 per die 210, a particular quantity of blocks 230 per plane 220, and a particular quantity of pages 240 per block 230, these quantities may be different than what is shown. In some implementations, the memory architecture 200 is a NAND memory architecture.

The die 210 is a structure made of semiconductor material, such as silicon. In some implementations, a die 210 is the smallest unit of memory that can independently execute commands. A memory device 120 may include one or more dies 210. In some implementations, the memory device 120 may include multiple dies 210. In this case, multiples dies 210 may each perform a respective memory operation (e.g., a read operation, a write operation, or an erase operation) in parallel. For example, a local controller 125 of the memory device 120 may be configured to concurrently perform memory operations on multiple dies 210 for parallel control.

Each die 210 of a memory device 120 includes one or more planes 220. A plane 220 is sometimes called a memory plane. In some implementations, identical and concurrent operations can be performed on multiple planes 220 (sometimes with restrictions). For example, a multi-plane command (e.g., a multi-plane read command or a multi-plane write command) may be executed on multiple planes 220 concurrently, whereas a single plane command (e.g., a single plane read command or a single plane write command) may be executed on a single plane 220. A logical unit of the memory device 120 may include one or more planes 220 of a die 210. In some implementations, a logical unit may include all planes 220 of a die 210 and may be equivalent to a die 210. Alternatively, a logical unit may include fewer than all planes 220 of a die 210. A logical unit may be identified by a logical unit number (LUN). Depending on the context, the term “LUN” may refer to a logical unit or an identifier (e.g., a number) of that logical unit.

Each plane 220 includes multiple blocks 230. A block 230 is sometimes called a memory block. Each block 230 includes multiple pages 240. A page 240 is sometimes called a memory page. A block 230 is the smallest unit of memory that can be erased. In other words, an individual page 240 of a block 230 cannot be erased without erasing every other page 240 of the block 230. A page 240 is the smallest unit of memory to which data can be written (i.e., the smallest unit of memory that can be programmed with data). The terminology “programming” memory and “writing to” memory may be used interchangeably. A page 240 may include multiple memory cells that are accessible via the same access line (sometimes called a word line). In some implementations, a block 230 may be divided into multiple sub-blocks. A sub-block is a portion of a block 230 and may include a subset of pages 240 of the block and/or a subset of memory cells of the block 230.

In some implementations, read and write operations are performed for a specific page 240, while erase operations are performed for a block 230 (e.g., all pages 240 in the block 230). In some implementations, to prevent wearing out of memory, all pages 240 of a block 230 may be programmed before the block 230 is erased to enable a new program operation to be performed to a page 240 of the block 230. After a page 240 is programmed with data (called “old data” below), that data can be erased, but that data cannot be overwritten with new data prior to being erased. The erase operation would erase all pages 240 in the block 230, and erasing the entire block 230 every time that new data is to replace old data would quickly wear out the memory cells of the block 230. Thus, rather than performing an erase operation, the new data may be stored in a new page (e.g., an empty page), as shown by reference number 250, and the old page that stores the old data may be marked as invalid, as shown by reference number 260. The memory device 120 may then point operations associated with the data to the new page (e.g., in an address table) and may track invalid pages to prevent program operations from being performed on invalid pages prior to an erase operation.

When a block 230 satisfies an erasure condition, the memory device 120 may select the block 230 for erasure, copy the valid data of the block 230 (e.g., to a new block 230 or to the same block 230 after erasure), and erase the block 230. For example, the erasure condition may be that all pages 240 of the block 230 or a threshold quantity or percentage of pages 240 of the block 230 are unavailable for further programming (e.g., are either invalid or already store valid data). As another example, the erasure condition may be that a quantity or percentage of free pages 240 of the block 230 (e.g., pages 240 that are available to be written) is less than or equal to a threshold. The process of selecting a block 230 satisfying an erasure condition, copying valid pages 240 of that block 230 to a new block 230 (or the same block 230 after erasure), and erasing the block 230 is sometimes called garbage collection and is used to free up memory space of the memory device 120.

In some examples, access lines associated with pages 240 of a first block 230 may be coupled with access lines associated with pages 240 of a second block 230, such as via one or more conductive paths. The memory device 120 may perform a staggered programming operation to store data across a first access line of the first block 230 and a second access line of the second block 230. For example, the staggered programming operation may include a first duration in which the first access line is activated and the second access line is deactivated. The staggered programming operation may include a second duration, subsequent to the first duration, in which the first access line is deactivated and the second access line is activated, as described in greater detail elsewhere herein. Due to the coupling of the first access line and the second access line, energy from the first access line may flow to the second access line during the second duration, which may aid in activating the second access line. By staggering programming operations, the memory device 120 may transfer energy that would otherwise be lost (e.g., dissipated as heat) from the first access line to the second access line. Such energy transfer may reduce the amount of energy generated by the memory device 120 to activate the second access line, thus reducing power consumption of the memory device 120. Further, such energy transfer may reduce dissipated heat, which may improve the efficiency and/or effectivity of thermal management.

As indicated above, FIG. 2 is provided as an example. Other examples may differ from what is described with regard to FIG. 2.

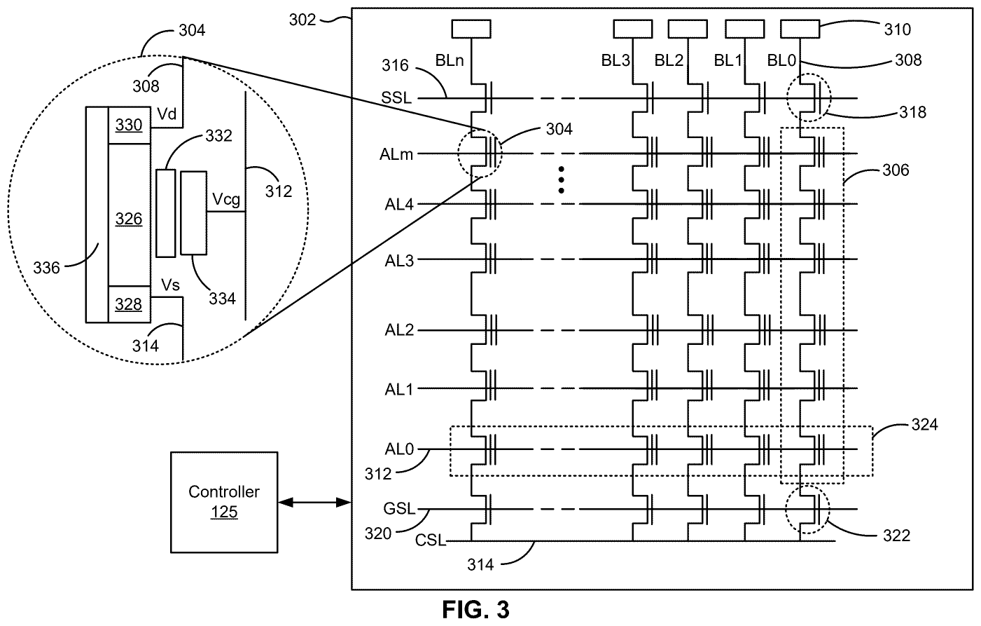

FIG. 3 is a diagram of example components included in a memory device 120. As described above in connection with FIG. 1, the memory device 120 may include a local controller 125 and one or more memory arrays 130. As shown in FIG. 3, the memory device 120 may include a memory array 302, which may correspond to a non-volatile memory array.

In FIG. 3, the memory array 302 is a NAND memory array. However, in some implementations, the memory array 302 may be another type of memory array, such as a NOR memory array, a resistive RAM (RRAM) memory array, a magnetoresistive RAM (MRAM) memory array, a ferroelectric RAM (FeRAM) memory array, a spin-transfer torque RAM (STT-RAM) memory array, or the like. In some implementations, the memory array 302 is part of a three-dimensional stack of memory arrays, such as 3D NAND flash memory, 3D NOR flash memory, or the like.

The memory array 302 includes multiple memory cells 304. A memory cell 304 may store an analog value, such as an electrical voltage or an electrical charge, that represents a data state (e.g., a digital value). The analog value and corresponding data state depend on a quantity of electrons trapped or present within a region of the memory cell 304 (e.g., in a charge trap, such as a floating gate), as described below.

A NAND string 306 (sometimes called a string) may include multiple memory cells 304 connected in series. A NAND string 306 is coupled to a bit line 308 (sometimes called a digit line or a column line, and shown as BLO-BLn). Data can be read from or written to the memory cells 304 of a NAND string 306 via a corresponding bit line 308 using one or more input/output (I/O) components 310 (e.g., an I/O circuit, an I/O bus, a page buffer, and/or a sensing component, such as a sense amplifier). Memory cells 304 of different NAND strings 306 (e.g., one memory cell 304 per NAND string 306) may be coupled with one another via access lines 312 (sometimes called word lines or row lines, and shown as AL0-ALm) that select which row (or rows) of memory cells 304 is affected by a memory operation (e.g., a read operation or a write operation).

A NAND string 306 may be connected to a bit line 308 at one end and a common source line (CSL) 314 at the other end. A string select line (SSL) 316 may be used to control respective string select transistors 318. A string select transistor 318 selectively couples a NAND string 306 to a corresponding bit line 308. A ground select line (GSL) 320 may be used to control respective ground select transistors 322. A ground select transistor 322 selectively couples a NAND string 306 to the common source line 314.

A “page” of memory (or “a memory page”) may refer to a group of memory cells 304 connected to the same access line 312, as shown by reference number 324. In some implementations (e.g., for single-level cells), the memory cells 304 connected to an access line 312 may be associated with a single page of memory. In some implementations (e.g., for multi-level cells), the memory cells 304 connected to an access line 312 may be associated with multiple pages of memory, where each page represents one bit stored in each of the memory cells 304 (e.g., a lower page that represents a first bit stored in each memory cell 304 and an upper page that represents a second bit stored in each memory cell 304). In NAND memory, a page is the smallest physically addressable data unit for a write operation (sometimes called a program operation).

In some implementations, a memory cell 304 is a floating-gate transistor memory cell. In this case, the memory cell 304 may include a channel 326, a source region 328, a drain region 330, a floating gate 332, and a control gate 334. The source region 328, the drain region 330, and the channel 326 may be on a substrate 336 (e.g., a semiconductor substrate). The memory device 120 may store a data state in the memory cell 304 by charging the floating gate 332 to a particular voltage associated with the data state and/or to a voltage that is within a range of voltages associated with the data state. This results in a predefined amount of current flowing through the channel 326 (e.g., from the source region 328 to the drain region 330) when a specified read voltage is applied to the control gate 334 (e.g., by a corresponding access line 312 connected to the control gate 334). Although not shown, a tunnel oxide layer (or tunnel dielectric layer) may be interposed between the floating gate 332 and the channel 326, and a gate oxide layer (e.g., a gate dielectric layer) may be interposed between the floating gate 332 and the control gate 334. As shown, a drain voltage Vd may be supplied from a bit line 308, a control gate voltage Vcg may be supplied from an access line 312, and a source voltage Vs may be supplied via the common source line 314 (which, in some implementations, is a ground voltage).

To write or program the memory cell 304, Fowler-Nordheim tunneling may be used. For example, a strong positive voltage potential may be created between the control gate 334 and the channel 326 (e.g., by applying a large positive voltage to the control gate 334 via a corresponding access line 312) while current is flowing through the channel 326 (e.g., from the common source line 314 to the bit line 308, or vice versa). The strong positive voltage at the control gate 334 causes electrons within the channel 326 to tunnel through the tunnel oxide layer and be trapped in the floating gate 332. These negatively charged electrons then act as an electron barrier between the control gate 334 and the channel 326 that increases the threshold voltage of the memory cell 304. The threshold voltage is a voltage required at the control gate 334 to cause current (e.g., a threshold amount of current) to flow through the channel 326. Fowler-Nordheim tunneling is an example technique for storing a charge in the floating gate, and other techniques, such as channel hot electron injection, may be used.

To read the memory cell 304, a read voltage may be applied to the control gate 334 (e.g., via a corresponding access line 312), and an I/O component 310 (e.g., a sense amplifier) may determine the data state of the memory cell 304 based on whether current passes through the memory cell 304 (e.g., the channel 326) due to the applied voltage. A pass voltage may be applied to all memory cells 304 (other than the memory cell 304 being read) in the same NAND string 306 as the memory cell 304 being read. For example, the pass voltage may be applied on each access line 312 other than the access line 312 of the memory cell 304 being read (e.g., where the read voltage is applied). The pass voltage is higher than the highest read voltage associated with any memory cell data states so that all of the other memory cells 304 in the NAND string 306 conduct, and the I/O component 310 can detect a data state of the memory cell 304 being read by sensing current (or lack thereof) on a corresponding bit line 308. For example, in a single-level memory cell that stores one of two data states, the data state is a “1” if current is detected, and the data state is a “0” if current is not detected. In a multi-level memory cell that stores one of three or more data states, multiple read voltages are applied, over time, to the control gate 334 to distinguish between the three or more data states and determine a data state of the memory cell 304.

To erase the memory cell 304, a strong negative voltage potential may be created between the control gate 334 and the channel 326 (e.g., by applying a large negative voltage to the control gate 334 via a corresponding access line 312). The strong negative voltage at the control gate 334 causes trapped electrons in the floating gate 332 to tunnel back across the oxide layer from the floating gate 332 to the channel 326 and to flow between the common source line 314 and the bit line 308. This removes the electron barrier between the control gate 334 and the channel 326 and decreases the threshold voltage of the memory cell 304 (e.g., to an empty or erased state, which may represent a “1”). In NAND memory, a block is the smallest unit of memory that can be erased. A block of NAND memory includes multiple pages. Thus, an individual page of a block cannot be erased without erasing every other page of the block. In some implementations, a block may be divided into multiple sub-blocks. A sub-block is a portion of a block and may include a subset of pages of the block and/or a subset of memory cells of the block.

In some examples, NAND memory may include multiple blocks. In such examples, access lines 312 of a first block may be coupled with access lines 312 associated with a second block, such as via one or more conductive paths. The NAND memory may perform a staggered programming operation to store data across a first access line of the first block and a second access line of the second block. For example, the staggered programming operation may include a first duration in which the first access line is activated and the second access line is deactivated. The staggered programming operation may include a second duration, subsequent to the first duration, in which the first access line is deactivated and the second access line is activated, as described in greater detail elsewhere herein. Due to the coupling of the first access line and the second access line, energy from the first access line may flow to the second access line during the second duration, which may aid in activating the second access line. By staggering programming operations, the NAND memory may transfer energy that would otherwise be lost (e.g., dissipated as heat) from the first access line to the second access line. Such energy transfer may reduce the amount of energy generated by the NAND memory to activate the second access line, thus reducing power consumption of the NAND memory. Further, such energy transfer may reduce dissipated heat, which may improve the efficiency and/or effectivity of thermal management.

As indicated above, FIG. 3 is provided as an example. Other examples may differ from what is described with regard to FIG. 3.

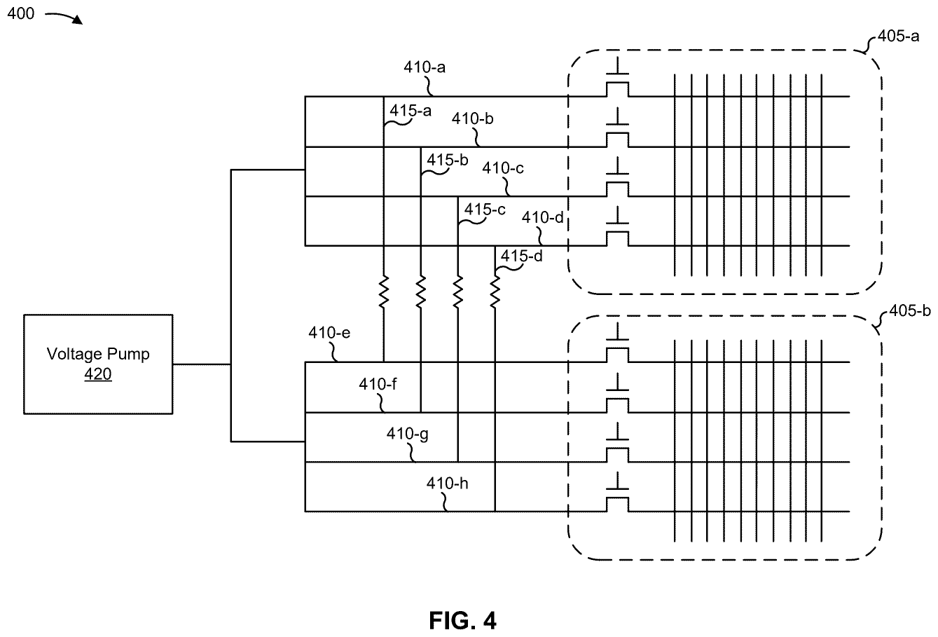

FIG. 4 shows an example of a system 400 that supports energy recycling in memory systems. The system 400 may be an example of or may be implemented in a memory apparatus, such as a memory system 110, a memory device 120, a memory system controller 115, a local controller 125, a die 210, and/or a memory array 302. The system 400 may include one or more blocks 405 of memory cells, such as a block 405-a and a block 405-b. A block 405 may be an example of a block 230. The blocks 405-a and 405-b may be included in the same plane (e.g., a plane 220), or may be included in separate planes. A block 405 may include one or more access lines 410 that may be used as part of access operations for memory cells of the block 405. An access line 410 may be an example of an access line 312 (e.g., a word line, a row line).

The access lines 410 of the block 405-a may be coupled with the access lines 410 of the block 405-b, such as via one or more conductive paths 415. For example, an access line 410-a may be coupled to an access line 410-e using a conductive path 415-a, an access line 410-b may be coupled to an access line 410-f using a conductive path 415-b, an access line 410-c may be coupled to an access line 410-g using a conductive path 415-c, and an access line 410-d may be coupled to an access line 410-h using a conductive path 415-d. In some implementations, the conductive paths 415 may include dedicated channels directly coupling access lines 410, such as one or more traces and/or one or more wires. Alternatively, the conductive paths 415 may couple access lines indirectly, such as through other components of the memory apparatus. In some implementations, the conductive paths 415 may include or may be coupled to respective switching components, such as transistors or other components configured to selectively isolate a first access line 410 from a second access line 410 or couple the first access line 410 to the second access lines 410. In some implementations, a conductive path 415 may include one or more resistive components. For example, a conductive path 415 may include one or more variable resistors. In such implementations, the system may configure (e.g., set, modify, adjust) the resistance of the conductive path 415 by adjusting respective resistances of the one or more variable resistors.

As used herein, “selectively” performing an operation means to either perform the operation or refrain from performing the operation. For example, selectively performing an operation based on whether a condition is satisfied means that the operation is performed if the condition is satisfied and that the operation is not performed if the condition is not satisfied (or vice versa). Thus, selectively performing an operation may include determining whether to perform the operation and then either performing the operation or refraining from performing the operation based on that determination. As used herein, “selectively” performing a first operation or a second operation means to perform either the first operation or the second operation. For example, selectively performing a first operation or a second operation based on whether a condition is satisfied means that the first operation is performed if the condition is satisfied and that the second operation is performed if the condition is not satisfied (or vice versa). Thus, selectively performing a first operation or a second operation may include determining whether to perform either the first operation or the second operation and then performing either the first operation or the second operation based on that determination.

The system 400 may perform access operations to memory cells associated with the access lines 410. In such access operations, the system 400 may perform one or more phases in which the system 400 activates and/or deactivates one or more of the access lines 410. To activate an access line 410, the system 400 may bias the access line 410 to a programming voltage, such as by using a voltage pump 420. Biasing an access line may include applying the programming voltage (e.g., seven volts (Vs)) to the access line 410 or otherwise raising the voltage of the access line 410 to the programming voltage. To deactivate an access line 410, the system 400 may bias the access line 410 to a low voltage, such as a ground voltage or other voltage lower than the programming voltage. For example, the system 400 may couple the access line 410 to a component, such as a ground voltage source or other node having a lower voltage than the programming voltage, to cause charge to flow from the access line 410 to the component, thus lowering the voltage.

As the system 400 performs access operations, or other operations using the access lines 410, energy may be transferred to and removed from the blocks 405. For example, due to the capacitance of the access lines 410 of the block 405-a (e.g., intrinsic capacitance, parasitic capacitance), activating an access line 410-a may cause energy (e.g., electrical potential energy) to flow to the block 405-a (e.g., as a result of charge being stored in the effective capacitor formed by the access lines 410 of the block 405-a). Similarly, deactivating the access line 410-a may cause energy to flow out of the block 405-a.

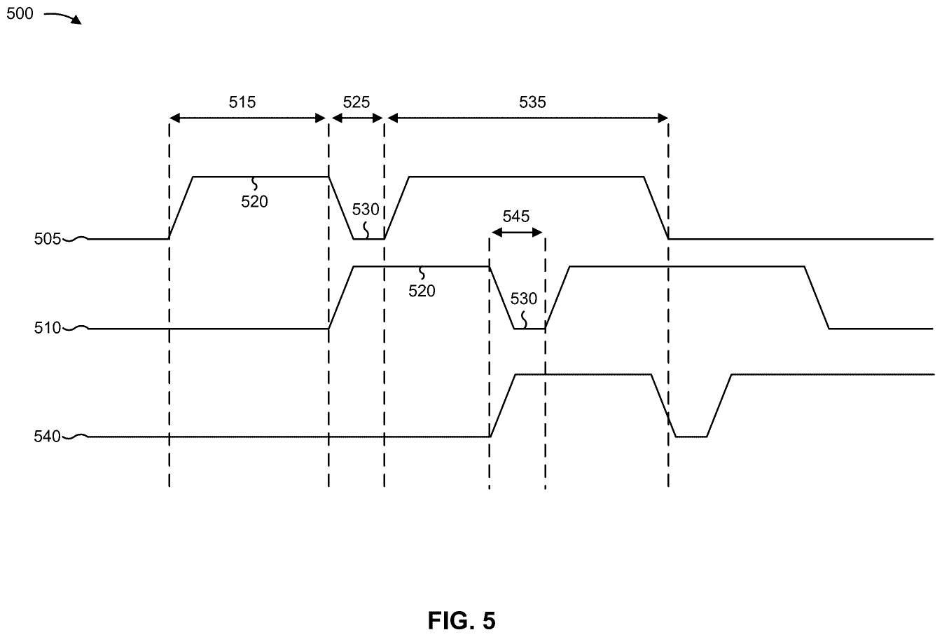

As described in greater detail in connection with FIG. 5, the system 400 may perform a staggered programming operation to store data across the access line 410-a and the access line 410-e. For example, the staggered programming operation may include a first duration in which the access line 410-a is activated and the access line 410-e is deactivated. The staggered programming operation may include a second duration, subsequent to the first duration, in which the access line 410-a is deactivated and the access line 410-e is activated. Due to the coupling of the access line 410-a and the access line 410-e, energy from the access line 410-a may flow to the access line 410-e (e.g., via the conductive path 415-a) during the second duration, which may aid in activating the access line 410-e. Such energy transfer may reduce the amount of energy supplied by the voltage pump 420 to activate the access line 410-e, thus reducing power consumption of the system 400. Further, such energy transfer may reduce dissipated heat, which may improve the efficiency and/or effectivity of thermal management.

As indicated above, FIG. 4 is provided as an example. Other examples may differ from what is described with regard to FIG. 4.

FIG. 5 shows an example of a timing diagram 500 that supports energy recycling in memory systems. A memory system 110, a memory device 120, a memory system controller 115, a local controller 125, a die 210, a memory array 302, and/or the system 400 may implement aspects of the timing diagram 500 as part of a staggered access operation for memory cells associated with one or more access lines (e.g., one or more access lines 410).

For example, the timing diagram 500 may be an example of a staggered programming operation to store data to memory cells associated with multiple access lines, such as the access line 410-a and the access line 410-e. In some examples, such as if the access line 410-a and the access line 410-e are included in separate planes, such a staggered programming operation may be an example of a staggered multi-plane programming operation. The timing diagram 500 may include one or more phases in which different access lines associated with the staggered programming operation are alternately activated and deactivated. For example, the timing diagram 500 may illustrate the change over time of a voltage 505 of a first access line of a first block (e.g., the access line 410-a of the block 405-a) and a voltage 510 of a second access line of a second block (e.g., the access line 410-e of the block 405-b).

The timing diagram 500 may include a duration 515 (e.g., a first phase of the staggered programming operation). During the duration 515, the memory system may activate the first access line, such as by biasing the first access line to a voltage 520 (e.g., a programming voltage). For example, the duration 515 may be a charging phase for the first access line. Further, during the duration 515, the memory system may refrain from activating the second access line (e.g., by deactivating the second access line or otherwise refraining from biasing the second access line to the voltage 520). In some examples, the memory system may isolate the first access line from the second access line during the duration 515 (e.g., using a switching component along a conductive path between the first access line and the second access line).

The timing diagram 500 may include a duration 525 (e.g., a second phase of the staggered programming operation) subsequent to the duration 515. During the duration 525, the memory system may deactivate the first access line, which may lower the voltage 505 of the first access line to a voltage 530 (e.g., the duration 525 may be a discharge phase for the first access line). For example, the memory system may refrain from biasing the first access line to the voltage 520. Rather, the memory system may bias the first access line to a lower voltage (e.g., a ground voltage or another voltage lower than the programming voltage 520). Further, during the duration 525, the memory system may activate the second access line (e.g., the activation of the first access line and the activation of the second access line may be staggered).

As part of activating the second access line, the memory system may couple the first access line to the second access line during the duration 525. Such coupling may cause energy to be transferred from the first access line to the second access line (e.g., may cause current and/or electrical potential to flow from the first access line to the second access line). The energy transferred to the second access line may aid in raising the voltage 510 of the second access line to the voltage level 520. Accordingly, the memory system may provide less energy to activate the second access line, compared with the energy provided to activate the first access line. Said another way, the energy used to activate the first access line may be at least partially recycled as part of activating the second access line. Such recycling of energy may reduce the power consumption of the memory system. Further, recycling energy by staggering access operations may reduce the amount of energy used to access a given amount of data (e.g., may reduce the energy per bit).

In some implementations, the staggered programming operations may be a multi-pass programming operation. For example, the memory system may apply a programming voltage multiple times to more reliably program data. In such implementations, the timing diagram 500 may include a duration 535, which may correspond to a second pass for the first access line. During the duration 535, the memory system may activate the first access line. Additionally, to prevent interference between programming of the first access line and programming of the second access line, the memory system may isolate the first access line from the second access line during the duration 535.

In some implementations, such as if the memory system includes more than two planes, the staggered programming operation may include accessing additional access lines across each of the planes. For example, the timing diagram 500 may illustrate the change over time of a voltage 540 of a third access line of a third block. The third access line may be coupled to the second access line via a conductive path. In such cases, the memory system may further stagger the activating of the third access line. For example, the timing diagram 500 may include a duration 545 subsequent to the duration 525. During the duration 545, the memory system may deactivate the second access line, which may lower the voltage 510 of the second access line to a voltage 530. For example, the memory system may refrain from biasing the second access line to the voltage 520. Rather, the memory system may bias the second access line to a lower voltage (e.g., a ground voltage or another voltage lower than the programming voltage 520). Further, during the duration 545, the memory system may activate the third access line. The memory system may include additional staggered activations, for example corresponding to the quantity of planes of a die of the memory system.

In some examples, an access line of a block may be coupled to multiple access lines of respective blocks. For example, the first access line may be coupled to the second access line and a fourth access line (e.g., via respective conductive paths), and/or the second access line may be coupled to the first access line and the third access line. In such examples, the staggered programming operation may be configured such that a discharge phase of a first group of access lines (e.g., the first access line and/or the third access line) coincides with (e.g., at least partially overlaps in time with) a charging phase of a second group of access lines (e.g., the second access line and/or the fourth access line).

The amount of energy transferred from the first access line to the second access line may be based on multiple factors, such as the relative lengths of the durations 515 and 525, the resistance between the first access line and the second access line, and/or the relative capacitances of a first block that includes the first access line and a second block that includes the second access line. To better optimize energy savings, the memory system may support configuring one or more of these factors. For example, the memory system may configure (e.g., change, modify, adjust) the duration 515 and/or the duration 525. Additionally, or alternatively, the memory system may configure the resistance between the first access line and the second access line (e.g., by configuring one or more variable resistors between the first access line and the second access line). Additionally, or alternatively, the memory system may configure the capacitance of the first block and/or the capacitance of the second block (e.g., by configuring one or more variable capacitors of the first block and/or the second block). In some examples, the first block and/or the second block may be extended across a single plane or across multiple planes. For example, if the first block is extended across multiple planes, then the first block may include one or more blocks and/or sub-blocks of memory cells, in which plane across which the first block is extended includes a respective portions of the one or more blocks and/or sub-blocks (e.g., each plane may include a single or multiple of the one or more blocks and/or sub-blocks). In some implementations, the memory system may configure the factors in response to obtaining a command from a host system (e.g., the host system 105) indicating a configuration for the factors. Additionally, or alternatively, the memory system may configure the factors independently (e.g., without receiving explicit instructions from the host system), such as during memory management or other configuration operations.

As indicated above, FIG. 5 is provided as an example. Other examples may differ from what is described with regard to FIG. 5.

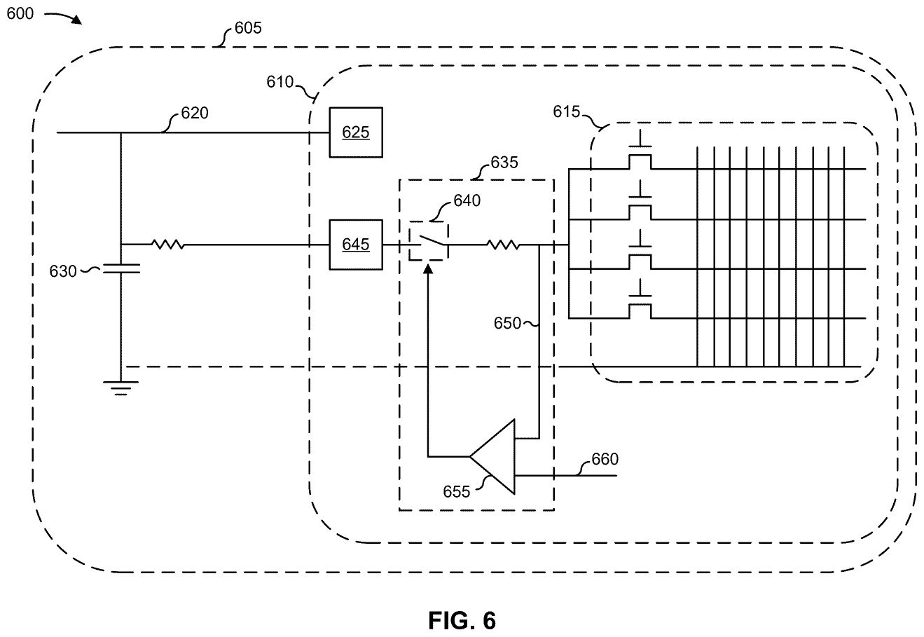

FIG. 6 shows an example of a system 600 that supports energy recycling in memory systems. The system 600 may be an example of or may be implemented in a memory apparatus, such as a memory system 110, a memory device 120, a memory system controller 115, a local controller 125, a die 210, and/or a memory array 302. The system 600 may include a memory system 605, which may be an example of the memory system 110. The memory system 605 may include one or more memory devices 610. A memory device 610 may be an example of a memory device 120. Each memory device 610 may include one or more blocks 615 of memory cells.

The memory system 605 may include a power management component configured to supply power to the one or more memory devices 610 using one or more voltage supply nodes 620. For example, each memory device 610 may include a voltage pad 625 coupled to a voltage supply node 620. In some cases, the memory device 610 may use the voltage supply node 620 as a reference voltage (e.g., as a logic “high” reference voltage). For example, the voltage supply node 620 may be a logic power voltage node, which may be referred to as a voltage collector-collector (VCC) node. In such cases, the memory system 605 may maintain the voltage supply node 620 at a first voltage, such as 2.5 V. Alternatively, the memory device 610 may use the voltage supply node 620 as part of powering output transistors used for data transfer. For example, the voltage supply node 620 may be an output stage logic power voltage node, which may be referred to as a VCCQ node. In such cases, the memory system 605 may maintain the voltage supply node 620 at a second voltage that is less than the first voltage, such as 1.2 V. In some implementations, the memory system 605 may use a same voltage supply node 620 to provide power to multiple memory devices 610. Said another way, multiple memory devices 610 may share a single voltage supply node 620.

The memory system 605 may include a reservoir capacitor 630 coupled to the one or more voltage supply nodes 620. The reservoir capacitor 630 may be exterior (e.g., external) to the one or more memory devices 610. For example, the reservoir capacitor 630 may be included in a package substrate of the memory system 605. The memory system 605 may use the reservoir capacitor 630 to store additional energy within the memory system 605 (e.g., as a reservoir of energy). The memory system 605 may use the reservoir capacitor 630 as a power supply to support powering operations of a memory device 610. For example, the memory device 610 may draw energy and/or current from the reservoir capacitor to power operations, such as access operations. Additionally, the reservoir capacitor 630 may support stabilizing noise in the voltage supplied by the one or more voltage supply nodes 620, for example by acting as a resistor-capacitor (RC) circuit for the memory system 605. Additionally, the memory system 605 may use the reservoir capacitor 630 to perform one or more operations in the case of an asynchronous power loss (APL). For example, if the memory system 605 unexpectedly loses power, then the power management component of the memory system 605 may no longer provide power to the one or more memory devices 610. However, because of the charge stored to the reservoir capacitor 630 during operation of the memory system 605, the reservoir capacitor 630 may continue to provide power to the one or more memory devices 610 after the unexpected power loss. The one or more memory devices 610 may use the power from the reservoir capacitor 630 to perform power loss operations, such as by completing one or more access commands, storing cached data to non-volatile memory, and/or performing memory management operations, among other examples.

A memory device 610 may include a recycle circuit 635 configured to provide energy to the reservoir capacitor 630. For example, the recycle circuit 635 may include a switching component 640 configured to selectively couple one or more access lines (e.g., access lines 312, access lines 410) of a block 615 of the memory device 610 with a voltage pad 645 or isolate the access line(s) from the voltage pad 645 based on a voltage 650 of the access line(s). The voltage pad 645 may be coupled to the reservoir capacitor 630. Accordingly, if a voltage 650 of the access line(s) is sufficiently high (e.g., higher than a threshold) and the access line(s) are coupled to the voltage pad 645, then current may flow from the access line(s) to the reservoir capacitor 630, and thus provide energy to the reservoir capacitor 630. In some examples, the voltage pad 645 may be a dedicated pad used for energy recycling. Alternatively, the system 600 may use the voltage pad 645 for other purposes. For example, the voltage pad 645 may be a programming power voltage (VPP) pad used to supply voltage and/or energy for performing programming operations.

For example, the recycle circuit 635 may include a comparator 655 configured to activate the switching component 640, which may couple the access line(s) to the voltage pad 645, or deactivate the switching component 640, which may isolate the access line(s) from the voltage pad 645, based on comparing the voltage 650 with a reference voltage 660. In some implementations, the reference voltage 660 may be configured to be higher than the voltage of the voltage supply node 620 (e.g., by an offset value). For example, if the voltage supply node 620 is a VCC node, then the reference voltage 660 may be higher than the first voltage, such as 2.7 V. Alternatively, if the voltage supply node 620 is a VCCQ node, then the reference voltage 660 may be higher than the second voltage, such as 1.5 V.

The comparator 655 may determine whether the voltage 650 satisfies a threshold (e.g., whether the voltage 650 is greater than or equal to the reference voltage 660). If the comparator 655 determines that the voltage satisfies the threshold, then the comparator 655 may activate the switching component 640. Accordingly, current may flow from the access line(s) to the reservoir capacitor 630, and thus the access line(s) may provide energy to the reservoir capacitor 630. Alternatively, if the comparator 655 determines that the voltage 650 does not satisfy the threshold, then the comparator may deactivate the switching component 640, which may prevent or mitigate current from flowing from the reservoir capacitor 630 to the access line(s).

The memory device 610 (e.g., a controller of the memory device 610, such as a local controller 125) may operate the recycle circuit 635 using firmware or other programmed instructions to improve the efficiency of the recycle circuit 635. For example, the memory device 610 may prevent the comparator 655 from activating the switching component 640 based on one or more access operation conditions of the system 600, such as whether the memory device 610 is performing a discharge phase on the access line(s). For example, the comparator 655 may selectively activate or deactivate the switching component 640 based on an access phase of the block 615. If access line(s) of the block 615 are undergoing a discharge phase (e.g., the duration 525), and if the voltage 650 satisfies the threshold, then the comparator 655 may activate the switching component 640. Alternatively, if the access line(s) of the block 615 are not undergoing a discharge phase, then the comparator 655 may deactivate the switching component 640, regardless of whether the voltage 650 satisfies the threshold.

By selectively coupling the access line(s) to the voltage pad 645 or isolating the access line(s) from the voltage pad 645, the memory device 610 may provide energy to the reservoir capacitor 630 that would otherwise be lost, such as via heat dissipation or other mechanisms. The reservoir capacitor 630 to may redistribute (e.g., via the voltage supply node 620) the provided energy back to the memory device 610, and/or other memory devices 610 of the memory system 605. Such redistribution may reduce the power consumption of the memory system 605. Further, recycling energy may reduce the amount of energy used to access a given amount of data (e.g., may reduce the energy per bit). Such reduced energy per bit may allow the memory device 610 to perform additional operations in the case of an APL, which may improve the reliability of the memory system 605.

In some examples, the switching component 640 may include one or more transistors. For example, the switching component 640 may include a first transistor and a second transistor connected in series to selectively couple the access lines of the block 615 with the voltage pad 645. Said another way, the switching component 640 may include a first transistor and a second transistors, where a first terminal of the first transistor may be coupled to the voltage pad 645. A second terminal of the first transistor may be coupled to a first terminal of the second transistor. A second terminal of the second transistor may be coupled to the access lines of the block 615. A gate of the first transistor and a gate of the second transistor may be coupled to the output of the comparator 655, such that the comparator 655 may selectively activate or deactivate the first transistor and/or the second transistor based on the voltage 650 of the access lines, the reference voltage 660, and/or one or more access operation conditions of the system 600. In some implementations, the first transistor and the second transistor may each be an example of a p-type metal-oxide-semiconductor (PMOS) transistor. By using two PMOS transistors connected in series, the switching component 640 may mitigate reverse current (e.g., current flowing through the switching component 640 while the switching component 640 is deactivated) between the voltage pad 645 and the access lines of the block 615.

The amount of energy transferred from the access line(s) to the reservoir capacitor 630 may be based on multiple factors, such as the value of the reference voltage 660, the resistance between the access line(s) and the voltage pad 645, and/or the resistance between the voltage pad 645 and the reservoir capacitor 630. To better optimize energy savings, the memory system 605 and/or the memory device 610 may support configuring one or more of these factors. For example, the memory system 605 and/or the memory device 610 may configure (e.g., change, modify, adjust) the value of the reference voltage 660. Additionally, or alternatively, the memory system 605 and/or the memory device 610 may configure the resistance between the access line(s) and the voltage pad 645, and/or the resistance between the voltage pad 645 and the reservoir capacitor 630 (e.g., by configuring one or more variable resistors between the resistance between the access line(s) and the voltage pad 645, and/or one or more variable resistors between the voltage pad 645 and the reservoir capacitor 630). In some implementations, the memory system 605 and/or the memory device 610 may configure the factors in response to obtaining a command from a host system (e.g., the host system 105) indicating a configuration for the factors. Additionally, or alternatively, the memory system 605 and/or the memory device 610 may configure the factors independently (e.g., without receiving explicit instructions from the host system), such as during memory management or other configuration operations.

As indicated above, FIG. 6 is provided as an example. Other examples may differ from what is described with regard to FIG. 6.

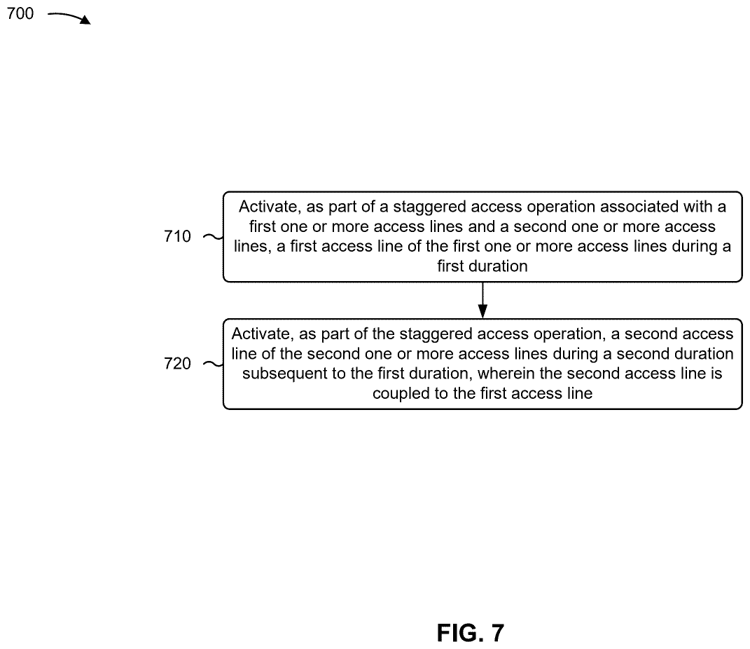

FIG. 7 is a flowchart of an example method 700 associated with energy recycling in memory systems. In some implementations, a memory device (e.g., the memory device 120) may perform or may be configured to perform the method 700. In some implementations, another device or a group of devices separate from or including the memory device (e.g., the system 100, the memory system 110, and/or the memory system controller 115) may perform or may be configured to perform the method 700. Additionally, or alternatively, one or more components of the memory device (e.g., a local controller 125 and/or a memory array 130) may perform or may be configured to perform the method 700. Thus, means for performing the method 700 may include the memory device and/or one or more components of the memory device. Additionally, or alternatively, a non-transitory computer-readable medium may store one or more instructions that, when executed by the memory device (e.g., the local controller 125 of the memory device 120), cause the memory device to perform the method 700.

As shown in FIG. 7, the method 700 may include activating, as part of a staggered access operation associated with a first one or more access lines and a second one or more access lines, a first access line of the first one or more access lines during a first duration (block 710). As further shown in FIG. 7, the method 700 may include activating, as part of the staggered access operation, a second access line of the second one or more access lines during a second duration subsequent to the first duration, wherein the second access line is coupled to the first access line (block 720).

The method 700 may include additional aspects, such as any single aspect or any combination of aspects described below and/or described in connection with one or more other methods or operations described elsewhere herein.

In a first aspect, the method 700 includes refraining, during the first duration, from activating the second access line, and refraining, during the second duration, from activating the first access line.

In a second aspect, alone or in combination with the first aspect, the staggered access operation causes, during the second duration, a charge to be transferred from the first access line to the second access line.

Although FIG. 7 shows example blocks of a method 700, in some implementations, the method 700 may include additional blocks, fewer blocks, different blocks, or differently arranged blocks than those depicted in FIG. 7. Additionally, or alternatively, two or more of the blocks of the method 700 may be performed in parallel. The method 700 is an example of one method that may be performed by one or more devices described herein. These one or more devices may perform or may be configured to perform one or more other methods based on operations described herein.

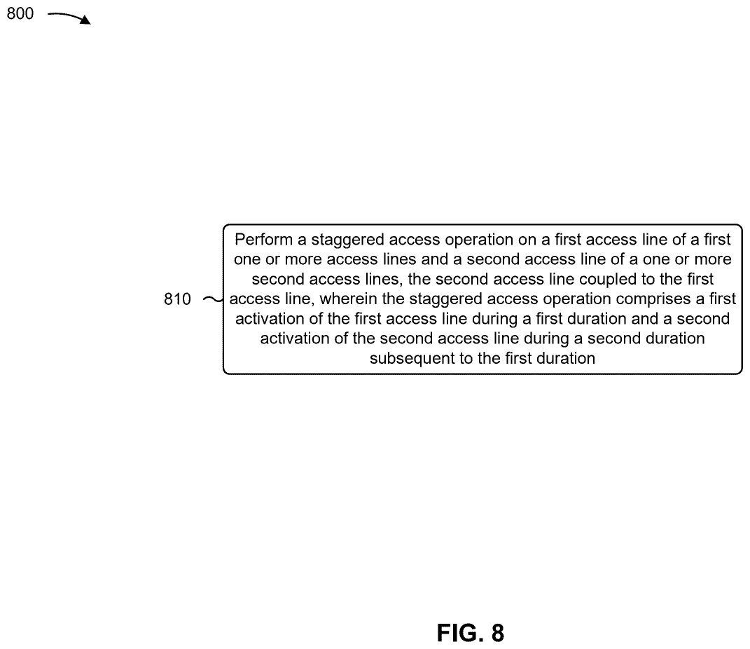

FIG. 8 is a flowchart of an example method 800 associated with energy recycling in memory systems. In some implementations, a memory apparatus (e.g., the memory device 120) may perform or may be configured to perform the method 800. In some implementations, another device or a group of devices separate from or including the memory apparatus (e.g., the system 100, the memory system 110, and/or the memory system controller 115) may perform or may be configured to perform the method 800. Additionally, or alternatively, one or more components of the memory apparatus (e.g., a local controller 125 and/or a memory array 130) may perform or may be configured to perform the method 800. Thus, means for performing the method 800 may include the memory apparatus and/or one or more components of the memory apparatus. Additionally, or alternatively, a non-transitory computer-readable medium may store one or more instructions that, when executed by the memory apparatus (e.g., the local controller 125 of the memory device 120), cause the memory apparatus to perform the method 800.

As shown in FIG. 8, the method 800 may include performing a staggered access operation on a first access line of a first one or more access lines and a second access line of a one or more second access lines, the second access line coupled to the first access line, wherein the staggered access operation comprises a first activation of the first access line during a first duration and a second activation of the second access line during a second duration subsequent to the first duration (block 810).

The method 800 may include additional aspects, such as any single aspect or any combination of aspects described below and/or described in connection with one or more other methods or operations described elsewhere herein.

In a first aspect, performing the staggered access operation comprises biasing, during the first duration, to the first access line to a voltage, refraining, during the first duration, from biasing the second access line to the voltage, biasing, during the second duration, the second access line to the voltage, and refraining, during the second duration, from biasing the first access line to the voltage.

In a second aspect, alone or in combination with the first aspect, the staggered access operation causes, during the second duration, a charge to be transferred from the first access line to the second access line.

In a third aspect, alone or in combination with one or more of the first and second aspects, the staggered access operation further comprises a third activation of a third access line of one or more third access lines during the first duration, wherein the third access line is coupled to the second access line.

In a fourth aspect, alone or in combination with one or more of the first through third aspects, the staggered access operation further comprises a third activation of a third access line of one or more third access lines during the second duration, wherein the third access line is coupled to the first access line.

In a fifth aspect, alone or in combination with one or more of the first through fourth aspects, the one or more first access lines are included in a first block of memory cells and the one or more second access lines are included in a second block of memory cells different than the first block of memory cells.

In a sixth aspect, alone or in combination with one or more of the first through fifth aspects, the one or more first access lines are included in a first plane and the one or more second access lines are included in a second plane different than the first plane.

In a seventh aspect, alone or in combination with one or more of the first through sixth aspects, the method 800 includes configuring at least one of a first length of the first duration or a second length of the second duration.

In an eighth aspect, alone or in combination with one or more of the first through seventh aspects, the staggered access operation is a program operation to store data to the memory system, wherein a first portion of the data is stored to first memory cells associated with the first access line and a second portion of the data is stored to second memory cells associated with the second access line.

In a ninth aspect, alone or in combination with one or more of the first through eighth aspects, the first access line is a first word line and the second access line is a second word line.

Although FIG. 8 shows example blocks of a method 800, in some implementations, the method 800 may include additional blocks, fewer blocks, different blocks, or differently arranged blocks than those depicted in FIG. 8. Additionally, or alternatively, two or more of the blocks of the method 800 may be performed in parallel. The method 800 is an example of one method that may be performed by one or more devices described herein. These one or more devices may perform or may be configured to perform one or more other methods based on operations described herein.

In some implementations, a memory device includes a first one or more access lines; a second one or more access lines; and one or more controllers configured to: perform a staggered access operation on a first access line of the first one or more access lines and a second access line of the one or more second access lines, the second access line coupled to the first access line, wherein the staggered access operation comprises a first activation of the first access line during a first duration and a second activation of the second access line during a second duration subsequent to the first duration.

In some implementations, a method includes activating, by a memory device and as part of a staggered access operation associated with a first one or more access lines and a second one or more access lines, a first access line of the first one or more access lines during a first duration; and activating, by the memory device and as part of the staggered access operation, a second access line of the second one or more access lines during a second duration subsequent to the first duration, wherein the second access line is coupled to the first access line.

In some implementations, a memory device includes one or more access lines; a voltage pad configured to couple to a reservoir capacitor; and a recycle circuit configured to selectively couple the one or more access lines to the reservoir capacitor via the voltage pad or isolate the one or more access lines from the reservoir capacitor based on a first voltage of the one or more access lines.

In some implementations, a system includes a reservoir capacitor a voltage supply node coupled to the reservoir capacitor; and a first memory device coupled to the voltage supply node, the first memory device comprising: a first one or more access lines; a voltage pad configured to couple to the reservoir capacitor; and a recycle circuit configured to selectively couple the first one or more access lines to the reservoir capacitor via the voltage pad or isolate the first one or more access lines from the reservoir capacitor based on a first voltage of the first one or more access lines.

In some implementations, a method includes performing, by a memory system, a staggered access operation on a first access line of a first one or more access lines and a second access line of a one or more second access lines, the second access line coupled to the first access line, wherein the staggered access operation comprises a first activation of the first access line during a first duration and a second activation of the second access line during a second duration subsequent to the first duration.

In some implementations, an apparatus includes means for activating, as part of a staggered access operation associated with a first one or more access lines and a second one or more access lines, a first access line of the first one or more access lines during a first duration; and means for activating, as part of the staggered access operation, a second access line of the second one or more access lines during a second duration subsequent to the first duration, wherein the second access line is coupled to the first access line.

In some implementations, an apparatus includes means for performing a staggered access operation on a first access line of a first one or more access lines and a second access line of a one or more second access lines, the second access line coupled to the first access line, wherein the staggered access operation comprises a first activation of the first access line during a first duration and a second activation of the second access line during a second duration subsequent to the first duration.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
a first one or more access lines;
a second one or more access lines; and
one or more controllers configured to:
perform a staggered access operation on a first access line of the first one or more access lines and a second access line of the one or more second access lines, the second access line coupled to the first access line, wherein the staggered access operation comprises a first activation of the first access line during a first duration and a second activation of the second access line during a second duration subsequent to the first duration.

2. The memory device of claim 1, wherein, to perform the staggered access operation, the one or more controllers are configured to:
bias, during the first duration, to the first access line to a voltage;
refrain, during the first duration, from biasing the second access line to the voltage;
bias, during the second duration, the second access line to the voltage; and
refrain, during the second duration, from biasing the first access line to the voltage.

3. The memory device of claim 1, wherein the staggered access operation causes, during the second duration, a charge to be transferred from the first access line to the second access line.

4. The memory device of claim 1, further comprising:
a third access line of a third one or more access lines, wherein the third access line is coupled to the second access line, and wherein the staggered access operation further comprises a third activation of the third access line during the first duration.

5. The memory device of claim 1, further comprising:
a third access line of a third one or more access lines, wherein the third access line is coupled to the first access line, and wherein the staggered access operation further comprises a third activation of the third access line during the second duration.

6. The memory device of claim 1, further comprising:
a first block of memory cells comprising the first access line; and
a second block of memory cells comprising the second access line, the first block of memory cells different than the second block of memory cells.

7. The memory device of claim 1, further comprising:
a first plane comprising the first access line; and
a second plane comprising the second access line, the first plane different than the second plane.

8. The memory device of claim 1, wherein the one or more controllers are further configured to:
configure at least one of a first length of the first duration or a second length of the second duration.

9. The memory device of claim 1, wherein the staggered access operation is a program operation to store data to the memory device, wherein a first portion of the data is stored to first memory cells associated with the first access line and a second portion of the data is stored to second memory cells associated with the second access line.

10. The memory device of claim 1, wherein the first access line is a first word line and the second access line is a second word line.

11. A method, comprising:
activating, by a memory device and as part of a staggered access operation associated with a first one or more access lines and a second one or more access lines, a first access line of the first one or more access lines during a first duration; and
activating, by the memory device and as part of the staggered access operation, a second access line of the second one or more access lines during a second duration subsequent to the first duration, wherein the second access line is coupled to the first access line.

12. The method of claim 11, further comprising:
refraining, during the first duration, from activating the second access line; and
refraining, during the second duration, from activating the first access line.

13. The method of claim 11, wherein the staggered access operation causes, during the second duration, a charge to be transferred from the first access line to the second access line.

14. A memory device, comprising:
one or more access lines;
a voltage pad configured to couple to a reservoir capacitor; and
a recycle circuit configured to selectively couple the one or more access lines to the reservoir capacitor via the voltage pad or isolate the one or more access lines from the reservoir capacitor based on a first voltage of the one or more access lines.

15. The memory device of claim 14, wherein the recycle circuit comprises:
a switching component coupled between the voltage pad and the one or more access lines, wherein, to selectively couple the one or more access lines to the reservoir capacitor or isolate the one or more access lines from the reservoir capacitor, the recycle circuit is configured to determine whether the first voltage of the one or more access lines satisfies a threshold.

16. The memory device of claim 15, wherein the first voltage of the one or more access lines satisfies the threshold, and wherein the switching component is further configured to:
apply a second voltage to one or more transistors electrically positioned between the voltage pad and the one or more access lines to couple the voltage pad to the one or more access lines.

17. The memory device of claim 16, wherein the one or more transistors comprise a first PMOS transistor connected in series with a second PMOS transistor.

18. The memory device of claim 15, wherein the first voltage of the one or more access lines does not satisfy the threshold, and wherein the switching component is further configured to:
apply a second voltage to one or more transistors electrically positioned between the voltage pad and the one or more access lines to isolate the voltage pad from the one or more access lines.

19. The memory device of claim 15, wherein one or more controllers of the memory device are configured to configure the threshold.

20. The memory device of claim 14, wherein the reservoir capacitor is exterior to the memory device.

21. A system, comprising:
a reservoir capacitor
a voltage supply node coupled to the reservoir capacitor; and
a first memory device coupled to the voltage supply node, the first memory device comprising:
a first one or more access lines;
a voltage pad configured to couple to the reservoir capacitor; and
a recycle circuit configured to selectively couple the first one or more access lines to the reservoir capacitor via the voltage pad or isolate the first one or more access lines from the reservoir capacitor based on a first voltage of the first one or more access lines.

22. The system of claim 21, further comprising:
a second memory device coupled to the voltage supply node, the second memory device comprising:
a second one or more access lines;
a second voltage pad configured to couple to the reservoir capacitor; and
a second recycle circuit configured to selectively couple the second one or more access lines to the reservoir capacitor via the second voltage pad or isolate the second one or more access lines from the reservoir capacitor based on a second voltage of the second one or more access lines.

23. The system of claim 21, wherein the voltage supply node is a logic power voltage node.

24. The system of claim 21, wherein the voltage supply node is an output stage logic power voltage node.
